(19) United States
(12) Patent Application Publication
(10) Pub. No.: US 2026/0110917 A1
(43) Pub. Date: Apr. 23, 2026

(54) IMAGE SENSOR AND IMAGE SENSING SYSTEM INCLUDING THE SAME

(71) Applicant: SK hynix Inc., Icheon-si (KR)

(72) Inventor: Yuta SUZUKI, Tokyo (JP)

(21) Appl. No.: 19/296,573

(22) Filed: Aug. 11, 2025

(30) Foreign Application Priority Data
Oct. 22, 2024 (KR) 10-2024-0144821

(51) Int. Cl. G02B 30/20; H04N 25/13; H10F 39/00

(52) U.S. Cl. CPC G02B 30/20; H04N 25/134; H10F 39/802; H10F 39/8063; H10F 39/8053

(57) ABSTRACT

An image sensor includes a first pixel block including first pixel groups arranged in a Bayer pattern; and a second pixel block disposed adjacent to the first pixel block in a first direction and configured to include second pixel groups arranged in the Bayer pattern. Each of the first pixel groups and the second pixel groups includes first pixels and second pixels that are disposed in columns or rows and have different photosensitivities, and the first pixels included in the first pixel groups and the first pixels included in the second pixel groups are located at opposite positions to be disposed at different columns or different rows of the corresponding pixel groups.

### PRIORITY CLAIM AND CROSS-REFERENCE TO RELATED APPLICATION

This patent document claims the priority and benefits of Korean patent application No. 10-2024-0144821, filed on Oct. 22, 2024, which is incorporated by reference in its entirety as part of the disclosure of this patent document.

### TECHNICAL FIELD

The technology and implementations disclosed in this patent document generally relate to an image sensor capable of generating parallax images and an image sensing system capable of detecting a parallax required for autofocus using the parallax images.

### BACKGROUND

An image sensor is a device for capturing optical images by converting light into electrical signals using a photosensitive semiconductor material which reacts to light. With the recent development of computer and communication industries, the demand for high-performance image sensors is increasing in various fields such as digital cameras, camcorders, personal communication systems (PCSs), game consoles, robots, surveillance cameras, medical micro cameras, etc.

### SUMMARY

Various embodiments of the disclosed technology relate to an image sensing system that can generate high-sensitivity parallax images for a high dynamic range (HDR) by improving an arrangement structure of the high-sensitivity pixels for HDR or can generate low-sensitivity parallax images for HDR by improving an arrangement structure of the low-sensitivity pixels for HDR, and also relate to an image sensing system that can detect a parallax for autofocus using the parallax images.

In accordance with an embodiment of the disclosed technology, an image sensor may include a first pixel block including first pixel groups arranged in a Bayer pattern; and a second pixel block disposed adjacent to the first pixel block in a first direction and configured to include second pixel groups arranged in the Bayer pattern. Each of the first pixel groups and the second pixel groups includes first pixels and second pixels that are disposed in columns or rows and have different photosensitivities, and the first pixels included in the first pixel groups and the first pixels included in the second pixel groups are located at opposite positions to be disposed at different columns or different rows of the corresponding pixel groups.

In accordance with another embodiment of the disclosed technology, an image sensor may include: a first pixel block including first pixel groups arranged in a Bayer pattern; and a second pixel block disposed adjacent to the first pixel block in a first direction and configured to include second pixel groups arranged in the Bayer pattern. Each of the first pixel groups and the second pixel groups may include a plurality of first pixels and at least one second pixel that have different photosensitivities from the plurality of first pixels. A first arrangement pattern of the plurality of first pixels included in the first pixel groups and a second arrangement pattern of the plurality of first pixels included in the second pixel groups may be located symmetrical to each other in the first direction.

In accordance with another embodiment of the disclosed technology, an image sensing system may include an image sensor that is configured to convert an optical signal for a subject into an electrical signal, include a plurality of unit pixels including first pixels having a first photosensitivity and second pixels having a second photosensitivity different from the first photosensitivity, and generate first parallax images for a first direction and second parallax images for a second direction perpendicular to the first direction by using some first pixels or some second pixels from among the plurality of unit pixels; and a parallax calculator coupled to receive information on the first and second parallax images captured by the image sensor and structured to generate a first directional parallax by comparing the first parallax images with each other and a second directional parallax by comparing the second parallax images with each other.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing system according to an embodiment of the disclosed technology.

FIG. 2 is a block diagram illustrating an example of an image sensor shown in FIG. 1 according to an embodiment of the disclosed technology.

FIG. 3 is a schematic diagram illustrating an example structure of one pixel block of a pixel array shown in FIG. 2 according to an embodiment of the disclosed technology.

FIG. 4 is a schematic diagram illustrating an example structure of some regions in which pixel blocks of the pixel array shown in FIG. 2 are consecutively arranged according to an embodiment of the disclosed technology.

FIG. 5A is a diagram illustrating an example of a method for generating horizontal parallax images using pixel blocks of FIG. 4 and calculating a horizontal parallax using the generated horizontal parallax images according to an embodiment of the disclosed technology.

FIG. 5B is a diagram illustrating an example of a method for generating vertical parallax images using pixel blocks of FIG. 4 and calculating a vertical parallax using the generated vertical parallax images according to an embodiment of the disclosed technology.

FIG. 6 is a diagram illustrating an example of an arrangement structure of pixels according to another embodiment of the disclosed technology.

FIG. 7A is a diagram illustrating an example of a method for generating horizontal parallax images using pixel blocks of FIG. 6 and calculating a horizontal parallax using the generated horizontal parallax images according to an embodiment of the disclosed technology.

FIG. 7B is a diagram illustrating an example of a method for generating vertical parallax images using pixel blocks of FIG. 6 and calculating a vertical parallax using the generated vertical parallax images according to an embodiment of the disclosed technology.

FIG. 8A is a diagram illustrating an example case in which the centers of the corresponding arrangement patterns are located on the same line in a first direction so that upper and lower positions of a left parallax image and a right parallax image are aligned.

FIG. 8B is a diagram illustrating an example case in which the centers of the corresponding arrangement patterns are not located on the same line so that upper and lower positions of a left parallax image and a right parallax image are not aligned.

FIG. 8C is a diagram illustrating an example case in which the centers of the corresponding arrangement patterns are located on the same line in a second direction so that left and right positions of a top parallax image and a down parallax image are aligned.

FIG. 9 is a diagram illustrating an example of an arrangement structure of pixels according to another embodiment of the disclosed technology.

FIG. 10 is a diagram illustrating an example of an arrangement structure of pixels according to another embodiment of the disclosed technology.

### DETAILED DESCRIPTION

This patent document provides implementations and examples of an image sensor capable of generating parallax images and an image sensing system capable of detecting a parallax required for autofocusing using the parallax images, that may be used to substantially address one or more technical or engineering issues and mitigate limitations or disadvantages encountered in some other image sensors. Some implementations of the disclosed technology suggest examples of an image sensor that can generate high-sensitivity parallax images for a high dynamic range (HDR) by improving an arrangement structure of the high-sensitivity pixels for HDR or can generate low-sensitivity parallax images for HDR by improving an arrangement structure of the low-sensitivity pixels for HDR, and also relate to an image sensing system that can detect a parallax for autofocusing using the parallax images. In recognition of the issues above, the disclosed technology provides various implementations of the image sensing device that can generate high-sensitivity parallax images or low-sensitivity parallax images having the same parallax direction. The disclosed technology provides various implementations of the image sensing system that can detect a parallax for autofocus using the high-sensitivity images or the low-sensitivity images, and can thus detect a parallax even when the high-sensitivity images are saturated or a signal-to-noise ratio (SNR) of the low-sensitivity images is too low.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

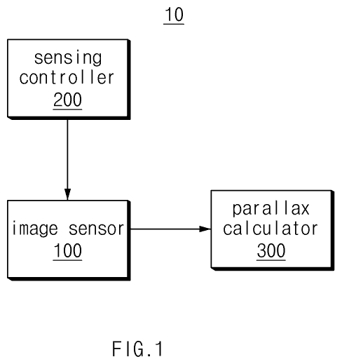

FIG. 1 is a block diagram illustrating an example of an image sensing system 10 according to an embodiment of the disclosed technology.

Referring to FIG. 1, the image sensing system 10 may include an image sensor 100, a sensing controller 200 and a parallax calculator 300. The components of the image sensing system illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light.

The image sensor 100 may capture an image of a target object (subject), may convert an optical signal for the captured image into an electrical signal, and may generate a parallax image. For example, the image sensor 100 may include a plurality of unit pixels for converting the optical signals obtained by capturing the subject into the electrical signals, and the pixel signals output from the plurality of unit pixels are converted into digital signals by an analog-to-digital converter (ADC), resulting in formation of parallax images. The plurality of unit pixels may include high-sensitivity pixels and low-sensitivity pixels for HDR imaging. The high-sensitivity pixels and the low-sensitivity pixels may have sensing conditions that are changed based on control of the sensing controller 200. Signals received from some pixels from among the high-sensitivity pixels or the low-sensitivity pixels may be used as signals for autofocus. For example, the image sensor 100 may generate parallax images for autofocus. The parallax images may include at least one high-sensitivity parallax image generated using signals received from some pixels from among the high-sensitivity pixels, or may include at least one low-sensitivity parallax image generated using pixel signals received from some pixels from among the low-sensitivity pixels.

The sensing controller 200 may control at least one of an exposure time, a conversion gain, and an analog gain of the image sensor 100 according to a preset logic. For example, the sensing controller 200 may include position information (position information within the pixel array) for preset high-sensitivity pixels and preset low-sensitivity pixels, may control at least one of the exposure time, the conversion gain, and the analog gain of each of the high-sensitivity pixels and the low-sensitivity pixels based on the position information, and may enable the image sensor 100 to perform HDR imaging

The parallax calculator 300 may calculate a horizontal parallax (e.g., a first directional parallax) or a vertical parallax (e.g., a second directional parallax) for the image sensor 100 using parallax images from the image sensor 100. At this time, the parallax calculator 300 may calculate the horizontal parallax or the vertical parallax by comparing the high-sensitivity parallax images with each other or by comparing the low-sensitivity parallax images with each other. For example, the parallax calculator 300 may calculate the horizontal parallax by comparing two high-sensitivity parallax images (i.e., a left high-sensitivity parallax image and a right high-sensitivity parallax image) in the horizontal direction with each other or by comparing two low-sensitivity parallax images (i.e., a left low-sensitivity parallax image and a right low-sensitivity parallax image) in the horizontal direction with each other. Alternatively, the parallax calculator 300 may calculate the vertical parallax by comparing two high-sensitivity parallax images (i.e., a top high-sensitivity parallax image and a down high-sensitivity parallax image) in the vertical direction with each other or by comparing two low-sensitivity parallax images (i.e., a top low-sensitivity parallax image and a down low-sensitivity parallax image) in the vertical direction with each other.

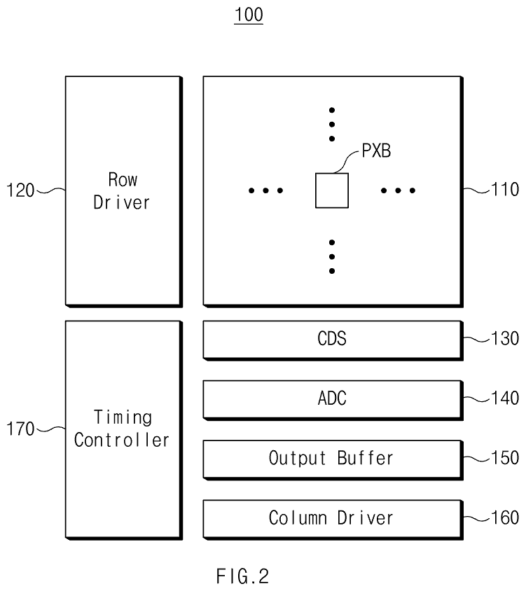

FIG. 2 is a block diagram illustrating an example of the image sensor 100 shown in FIG. 1 according to an embodiment of the disclosed technology.

Referring to FIG. 2, the image sensor 100 may include a pixel array 110, a row driver 120, a correlated double sampler (CDS) 130, an analog-to-digital converter (ADC) 140, an output buffer 150, a column driver 160, and a timing controller 170. The components of the image sensor illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light.

The pixel array 110 may include a plurality of pixel blocks (PXBs) arranged in a plurality of rows and a plurality of columns. Each pixel block (PXB) may include a plurality of pixel groups that are designed to selectively detect incident light of different colors and arranged in a Bayer pattern. Each pixel group may include a plurality of unit pixels. Within each pixel group, the unit pixels may include the same color filters to transmit light of the same color while blocking transmission of light in other colors and may share one common microlens to receive incident light to the different unit pixels within the same pixel group. Each unit pixel may include a photosensitive element that photoelectrically converts incident light, which is filtered by the color filter in that unit pixel, to generate an electrical signal corresponding to the incident light in a particular color for the corresponding pixel group to which the unit pixel belongs. For example, the photosensitive element may include a photodiode, a phototransistor, a photogate, a pinned photodiode, or a combination thereof. Each pixel group may include high-sensitivity pixels and low-sensitivity pixels.

The pixel array 110 may receive driving signals (for example, a row selection signal, a reset signal, a transfer signal, a conversion gain control signal, etc.) from the row driver 120. Upon receiving the driving signals, the unit pixels may be activated to perform the operations corresponding to the row selection signal, the reset signal, and the transfer signal. At this time, the transfer signal and the conversion gain control signal may be changed based on the control of the sensing controller 200.

The row driver 120 may activate the unit pixels based on control signals received from controller circuitry such as the timing controller 170. In some implementations, the row driver 120 may select one or more unit pixels arranged in one or more rows of the pixel array 110. The row driver 120 may enable the conversion gain control signal, the reset signal, the transfer signal, etc. for the unit pixels of the selected row line. At this time, the on/off operation of the conversion gain control signal and the timing of the transfer signal may be controlled based on the control of the timing controller 170. The pixel signals generated from the unit pixels of the selected row line may be output to the correlated double sampler (CDS) 130.

The correlated double sampler (CDS) 130 may remove undesired offset values of the unit pixels using correlated double sampling. In one example, the correlated double sampler (CDS) 130 may remove the undesired offset values of the unit pixels by comparing output voltages of pixel signals (of the unit pixels) obtained before and after photocharges generated by incident light are accumulated in the sensing node (i.e., a floating diffusion (FD) node). The correlated double sampler 130 may output the reference signal and the pixel signal as a correlated double sampling (CDS) signal to the analog-to-digital converter (ADC) 140.

The ADC 140 is used to convert analog CDS signals received from the CDS 130 into digital signals. The analog-to-digital converter (ADC) 140 may compare a ramp signal received from the timing controller 170 with the CDS signal received from the CDS 130, and may thus output a comparison signal indicating the result of comparison between the ramp signal and the CDS signal. The analog-to-digital converter (ADC) 140 may count a level transition time of the comparison signal in response to the ramp signal received from the timing controller 170, and may output a count value indicating the counted level transition time to the output buffer 150.

The output buffer 150 may temporarily store column-based image data provided from the ADC 140 based on control signals of the timing controller 170. The image data received from the ADC 140 may be temporarily stored in the output buffer 150 based on control signals of the timing controller 170. The output buffer 150 may provide an interface to compensate for data rate differences or transfer rate differences between the image sensor 100 and the parallax calculator 300.

The column driver 160 may select a column of the output buffer 150 upon receiving a control signal from the timing controller 170, and sequentially output the image data, which are temporarily stored in the selected column of the output buffer 150. In some implementations, upon receiving an address signal from the timing controller 170, the column driver 160 may generate a column selection signal based on the address signal, may select a column of the output buffer 150 using the column selection signal, and may control the data received from the selected column of the output buffer 150 to be output as raw image data.

The timing controller 170 may generate signals for controlling operations of the row driver 120, the ADC 140, the output buffer 150 and the column driver 160. The timing controller 170 may provide the row driver 120, the column driver 160, the ADC 140, and the output buffer 150 with a clock signal required for the operations of the respective components of the image sensor, a control signal for timing control, and address signals for selecting a row or column. The timing controller 170 may adjust the timing of transfer signals of a high-sensitivity pixel and a low-sensitivity pixel, the on/off operation of a conversion gain control signal, and the amplitude of a ramp signal, upon receiving a control signal from the sensing controller 200.

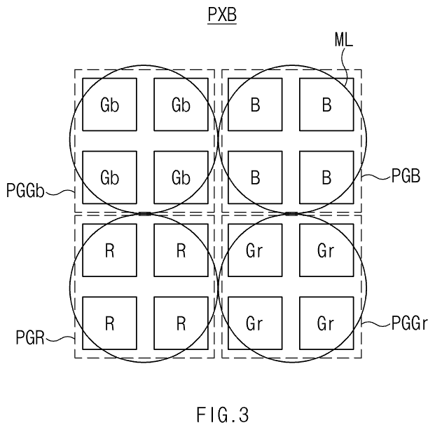

FIG. 3 is a schematic diagram illustrating an example structure of one pixel block of the pixel array shown in FIG. 2 according to an embodiment of the disclosed technology.

Referring to FIG. 3, each pixel block (PXB) may include a plurality of pixel groups (PGR, PGGr, PGGb, PGB) arranged adjacent to each other for filtering and detecting incident light of different colors such as a red (R) color for the pixel group PGR, a green (Gr) color for the pixel group PGGr, a green (Gb) color for the pixel group PGGb, and a blue (B) color for the pixel group PGB based on the Bayer pattern which includes two parts green, one part red, and one part blue. Each pixel group (PGR, PGGb, PGGr, PGB) may include a plurality of unit pixels sharing one microlens (ML) and having a color filter to transmit light in a same color while absorbing or blocking light in other colors.

The unit pixels of each pixel group (PGR, PGGb, PGGr, PGB) may be arranged adjacent to each other in an (M×N) matrix structure (where each of M and N is an integer of 2 or greater, and M and N may be the same or different from each other). For example, the pixel group (PGR) may include four unit pixels of red color (R) arranged in a (2×2) matrix structure sharing one microlens (ML). Each of the pixel groups (PGGr, PGGb) may include four unit pixels of green color (G) arranged in a (2×2) matrix structure while sharing one microlens (ML). The pixel group (PGB) may include four unit pixels of blue color (B) arranged in a (2×2) matrix structure sharing one microlens (ML). The pixel groups (PGR, PGGr, PGGb, PGB) may be arranged in a Bayer pattern.

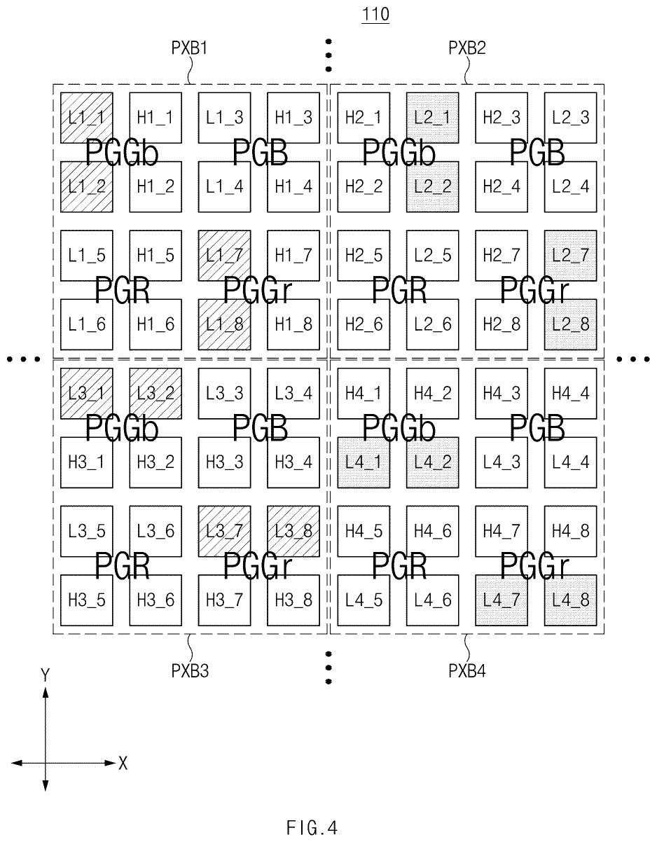

FIG. 4 is a schematic diagram illustrating an example structure of some regions in which pixel blocks of the pixel array shown in FIG. 2 are consecutively arranged according to an embodiment of the disclosed technology.

Referring to FIG. 4, the pixel array 110 may include a plurality of pixel blocks (PXB1˜PXB4) arranged adjacent to one another in a first direction (e.g., an X-axis direction along which PXB1 and PXB2 are located relative to each other) and a second direction (e.g., a Y-axis direction along which PXB1 and PXB3 are located relative to each other). Each of the pixel blocks (PXB1˜PXB4) may include pixel groups (PGR, PGGr, PGGb, PGB) having the same structure as in FIG. 3.

The pixel groups (PGR, PGGr, PGGb, PGB) may include high-sensitivity pixels (H1_1˜H4_8) and low-sensitivity pixels (L1_1˜L4_8) for HDR imaging. In the example in FIG. 4, each of the upper two pixel blocks PXB1 and PXB2 may include 8 high-sensitivity pixels in two columns and 8 low-sensitivity pixels in two columns and the 2 high-sensitivity pixel columns and 2 low-sensitivity pixel columns may spatially interleaved; whereas, each of the lower two pixel blocks PXB3 and PXB4 may include 8 high-sensitivity pixels in two row and 8 low-sensitivity pixels in two row and the 2 high-sensitivity pixel rows and 2 low-sensitivity pixel rows may spatially interleaved. For example, each of the unit pixels included in each pixel group (PGR, PGGr, PGGb, PGB) may correspond to any one of a high-sensitivity pixel and a low-sensitivity pixel.

Each of the high-sensitivity pixels (H1_1˜H4_8) may refer to a pixel having a relatively large increase in response due to an increase in the intensity of incident light. Here, the response may refer to a pixel signal generated by the high-sensitivity pixels (H1_1˜H4_8) detecting the intensity of incident light. In some implementations, each of the high-sensitivity pixels (H1_1˜H4_8) may refer to a pixel having a relatively high photosensitivity to incident light as compared to the low-sensitivity pixels (L1_1˜L4_8).

Each of the low-sensitivity pixels (L1_1˜L4_8) may refer to a pixel having a relatively small increase in response due to an increase in the intensity of incident light. In some implementations, each of the low-sensitivity pixels (L1_1˜L4_8) may refer to a pixel having a relatively low photosensitivity to incident light as compared to the high-sensitivity pixels (H1_1˜H4_8).

In the present embodiment, each pixel group (PGR, PGGb, PGGr, PGB) of the pixel blocks (PXB1˜PXB4) may include two high-sensitivity pixels and two low-sensitivity pixels. In some implementations, the arrangements/locations of the high-sensitivity pixels and the low-sensitivity pixels in two upper adjacent pixel blocks (PXB1, PXB2) from among the pixel blocks (PXB1˜PXB4) may be different from each other. For example, when each pixel group (PGR, PGGb, PGGr, PGB) of the pixel block (PXB1) includes the four unit pixels arranged in a (2×2) matrix structure including two rows and two columns, two unit pixels arranged in the first column (e.g., the left column) of each (2×2) matrix structure may be low-sensitivity pixels (L1_1˜L1_8) and two unit pixels arranged in the second column (e.g., the right column) of each (2×2) matrix structure may be high-sensitivity pixels (H1_1˜H1_8). On the other hand, when each pixel group (PGR, PGGb, PGGr, PGB) of the pixel block (PXB2) includes the four unit pixels arranged in a (2×2) matrix structure including two rows and two columns,, two unit pixels arranged in the first column (e.g., the left column) of each (2×2) matrix structure may be high-sensitivity pixels (H2_1˜H2_8) and two unit pixels arranged in the second column (e.g., the right column) of each (2×2) matrix structure may be low-sensitivity pixels (L2_1˜L2_8). In the implementations, while the low-sensitivity pixel, the high-sensitivity pixel, the low-sensitivity pixel, and the high-sensitivity pixel are sequentially arranged and interleaved along the first direction (e.g., the horizontal direction) in the pixel block (PXB1), the high-sensitivity pixel, the low-sensitivity pixel, the high-sensitivity pixel, and the low-sensitivity pixel are sequentially arranged and interleaved along the first direction in the pixel block (PXB2). In the example in FIG. 4, in two upper adjacent pixel blocks (PXB1, PXB2) from among the pixel blocks (PXB1˜PXB4), the high-sensitivity pixels and the low-sensitivity pixels may be located opposite to each other in the first direction (X direction). The high-sensitivity pixels and low-sensitivity pixels of such pixel blocks (PXB1, PXB2) may be used to generate two parallax images in the first direction (e.g., the horizontal direction or the X direction).

In some implementations, the arrangements/locations of the high-sensitivity pixels and the low-sensitivity pixels in two lower adjacent pixel blocks (PXB3, PXB4) from among the pixel blocks (PXB1˜PXB4) may be different from each other. For example, when each pixel group (PGR, PGGb, PGGr, PGB) of the pixel block (PXB3) includes the four unit pixels arranged in a (2×2) matrix structure including two rows and two columns, two unit pixels arranged in the first row (e.g., the upper row) of each (2×2) matrix structure may be low-sensitivity pixels (L3_1˜L3_8) and two unit pixels arranged in the second row (e.g., the lower row) of each (2×2) matrix structure may be high-sensitivity pixels (H3_1˜H3_8). On the other hand, when each pixel group (PGR, PGGb, PGGr, PGB) of the pixel block (PXB4) includes the four unit pixels arranged in a (2×2) matrix structure including two rows and two columns, two unit pixels arranged in the first row (e.g., the upper row) of each (2×2) matrix structure may be high-sensitivity pixels (H4_1˜H4_8) and two unit pixels arranged in the second row (e.g., the lower row) of each (2×2) matrix structure may be low-sensitivity pixels (L4_1˜L4_8). In the implementations, while the low-sensitivity pixel, the high-sensitivity pixel, the low-sensitivity pixel, and the high-sensitivity pixel are sequentially arranged along the second direction (e.g., the vertical direction) in the pixel block (PXB3), the high-sensitivity pixel, the low-sensitivity pixel, the high-sensitivity pixel, and the low-sensitivity pixel are sequentially arranged along the second direction in the pixel block (PXB4). In this case, in two lower adjacent pixel blocks (PXB3, PXB4) from among the pixel blocks (PXB1˜PXB4), the high-sensitivity pixels and the low-sensitivity pixels may be located opposite to each other in the second direction. The high-sensitivity pixels or low-sensitivity pixels of the pixel blocks (PXB3, PXB4) may be used to generate parallax images in the second direction (e.g., the vertical direction).

The image sensor 100 according to the present embodiment may include unit pixels (e.g., high-sensitivity pixels and low-sensitivity pixels) having different photosensitivities for HDR implementation. In some implementations, the unit pixels having the same photosensitivity may be located opposite to each other (e.g., being located at different columns/rows in the corresponding pixel groups) in adjacent pixel blocks for autofocus.

The pixel blocks (PXB1˜PXB4) arranged as in FIG. 4 may be formed at various positions within the pixel array 110.

In some implementations, in the arrangement of FIG. 4, the high-sensitivity pixels and the low-sensitivity pixels may be interchanged. For example, the low-sensitivity pixels may be formed at the positions of the high-sensitivity pixels shown in FIG. 4, and the high-sensitivity pixels may be formed at the positions of the low-sensitivity pixels shown in FIG. 4.

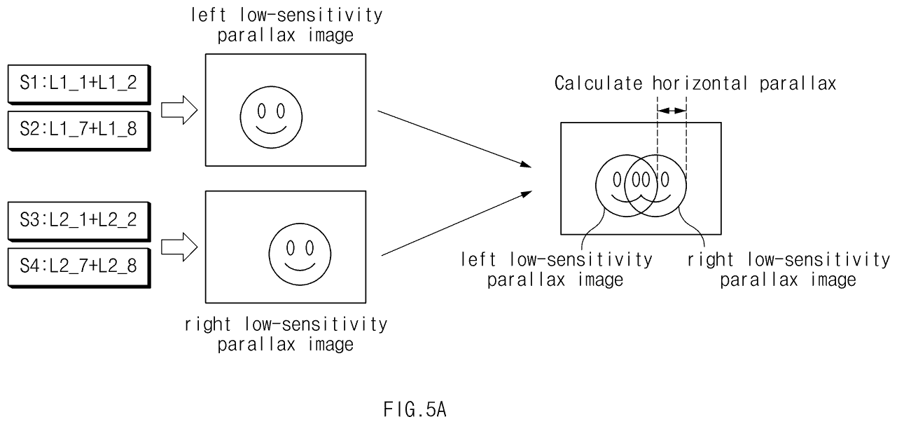

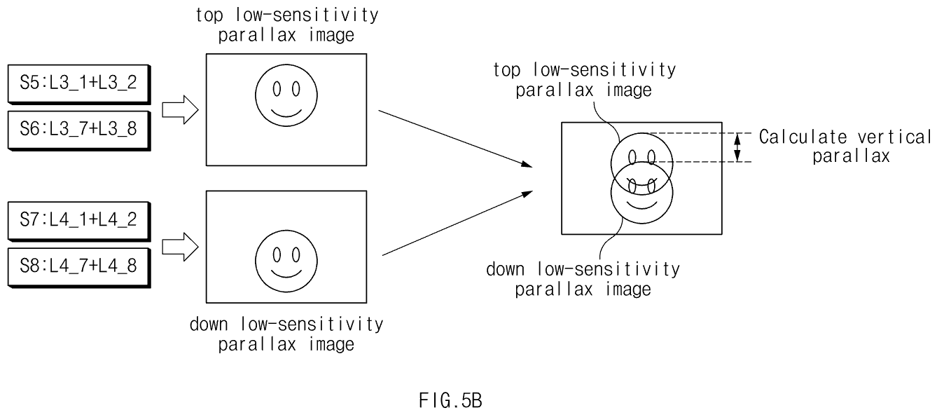

FIG. 5A is a diagram illustrating an example of a method for generating horizontal parallax images using pixel blocks of FIG. 4 and calculating a horizontal parallax using the generated horizontal parallax images according to an embodiment of the disclosed technology. FIG. 5B is a diagram illustrating an example of a method for generating vertical parallax images using pixel blocks of FIG. 4 and calculating a vertical parallax using the generated vertical parallax images according to an embodiment of the disclosed technology.

Referring to FIGS. 4 and 5A, the image sensor 100 may generate a left low-sensitivity parallax image using pixel signals of the low-sensitivity pixels (L1_1, L1_2, L1_7, L1_8) of the pixel groups (PGGb, PGGr) having the green color within the pixel block (PXB1). For example, the image sensor 100 may generate a left low-sensitivity parallax image by using a value (S1) obtained by summing signal values of low-sensitivity pixels (L1_1, L1_2) of the pixel group (PGGb) and another value (S2) obtained by summing signal values of low-sensitivity pixels (L1_7, L1_8) of the pixel group (PGGr) within the pixel block (PXB1). Although the present embodiment has disclosed that the left low-sensitivity parallax image is generated by using two values (S1, S2) as an example, other implementations are also possible. In some implementations, it should be noted that the left low-sensitivity parallax image may be generated by further using other pixel blocks in which low-sensitivity pixels are formed on the left side of each pixel block in the same manner as in the pixel block (PXB1).

In some implementations, the image sensor 100 may generate a right low-sensitivity parallax image by using pixel signals of the low-sensitivity pixels (L2_1, L2_2, L2_7, L2_8) of the pixel groups (PGGr, PGGb) having the green color within the pixel block (PXB2). For example, the image sensor 100 may generate a right low-sensitivity parallax image by using a value (S3) obtained by summing signal values of low-sensitivity pixels (L2_1, L2_2) of the pixel group (PGGb) and another value (S4) obtained by summing signal values of low-sensitivity pixels (L2_7, L2_8) of the pixel group (PGGr) within the pixel block (PXB2). Although the present embodiment has disclosed that the right low-sensitivity parallax image is generated by using two values (S3, S4) as an example, other implementations are also possible. In some implementations, it should be noted that the right low-sensitivity parallax image may be generated by further using other pixel blocks in which low-sensitivity pixels are formed on the right side of each pixel block in the same manner as in the pixel block (PXB2).

As described above, the image sensor 100 may generate the left parallax image and the right parallax image by using some unit pixels in the two adjacent pixel blocks from among pixel blocks, which are located opposite to each other in the first direction (e.g., being located at different columns in the corresponding pixel groups) and have the same photosensitivity.

The parallax calculator 300 may calculate a first directional parallax (i.e., a horizontal parallax) by comparing the left low-sensitivity parallax image formed by the image sensor 100 with the right low-sensitivity parallax image formed by the image sensor 100.

Referring to FIGS. 4 and 5B, the image sensor 100 may generate a top low-sensitivity parallax image using pixel signals of the low-sensitivity pixels (L3_1, L3_2, L3_7, L3_8) of the pixel groups (PGGb, PGGr) having the green color within the pixel block (PXB3). For example, the image sensor 100 may generate a top low-sensitivity parallax image by using a value (S5) obtained by summing signal values of low-sensitivity pixels (L3_1, L3_2) of the pixel group (PGGb) and another value (S6) obtained by summing signal values of low-sensitivity pixels (L3_7, L3_8) of the pixel group (PGGr) within the pixel block (PXB1). Although the present embodiment has disclosed that the top low-sensitivity parallax image is generated by using two values (S5, S6) as an example, other implementations are also possible. In some implementations, it should be noted that the top low-sensitivity parallax image may be generated by further using other pixel blocks in which low-sensitivity pixels are formed on the upper side of each pixel block in the same manner as in pixel groups (PGGb, PGGr) of the pixel block PXB3.

In some implementations, the image sensor 100 may generate a down low-sensitivity parallax image by using pixel signals of the low-sensitivity pixels (L4_1, L4_2, L4_7, L4_8) of the pixel groups (PGGr, PGGb) having the green color within the pixel block (PXB4). For example, the image sensor 100 may generate a down low-sensitivity parallax image by using a value (S7) obtained by summing signal values of low-sensitivity pixels (L4_1, L4_2) of the pixel group (PGGb) and another value (S8) obtained by summing signal values of low-sensitivity pixels (L4_7, L4_8) of the pixel group (PGGr) within the pixel block (PXB4). Although the present embodiment has disclosed that the down low-sensitivity parallax image is generated by using two values (S7, S8) as an example, other implementations are also possible. In some implementations, it should be noted that the down low-sensitivity parallax image may be generated by further using other pixel blocks in which low-sensitivity pixels are formed on the lower side of each pixel block in the same manner as in pixel groups (PGGb, PGGr) of the pixel block (PXB4).

As described above, the image sensor 100 may generate the top parallax image and the down parallax image by using some unit pixels in the two adjacent pixel blocks from among pixel blocks, which are located opposite to each other in the second direction (e.g., being located at different rows in the corresponding pixel groups) and have the same photosensitivity.

The parallax calculator 300 may calculate a second directional parallax (i.e., a vertical parallax) by comparing the top low-sensitivity parallax image formed by the image sensor 100 with the down low-sensitivity parallax image formed by the image sensor 100.

Although the above-described embodiment has disclosed the example case in which the image sensor 100 forms parallax images using only the low-sensitivity pixels as an example, other implementations are also possible. In some implementations, it should be noted that the image sensor 100 may also form parallax images using only the high-sensitivity pixels. For example, the image sensor 100 may generate a right high-sensitivity parallax image using high-sensitivity pixels (H1_1, H1_2, H1_7, H1_8) of pixel groups (PGGb, PGGr) within the pixel block (PXB1), and may generate a left high-sensitivity parallax image using high-sensitivity pixels (H2_1, H2_2, H2_7, H2_8) of pixel groups (PGGr, PGGb) within the pixel block (PXB2). In addition, the image sensor 100 may generate a down high-sensitivity parallax image using the high-sensitivity pixels (H3_1, H3_2, H3_7, H3_8) of the pixel groups (PGGb, PGGr) within the pixel block (PXB3), and may generate a top high-sensitivity parallax image using the high-sensitivity pixels (H4_1, H4_2, H4_7, H4_8) of the pixel groups (PGGr, PGGb) within the pixel block (PXB4).

Even when the high-sensitivity pixels and the low-sensitivity pixels of FIG. 4 are interchanged, the image sensing system may generate parallax images, and may compare the generated parallax images with each other to calculate a parallax using the above-described method.

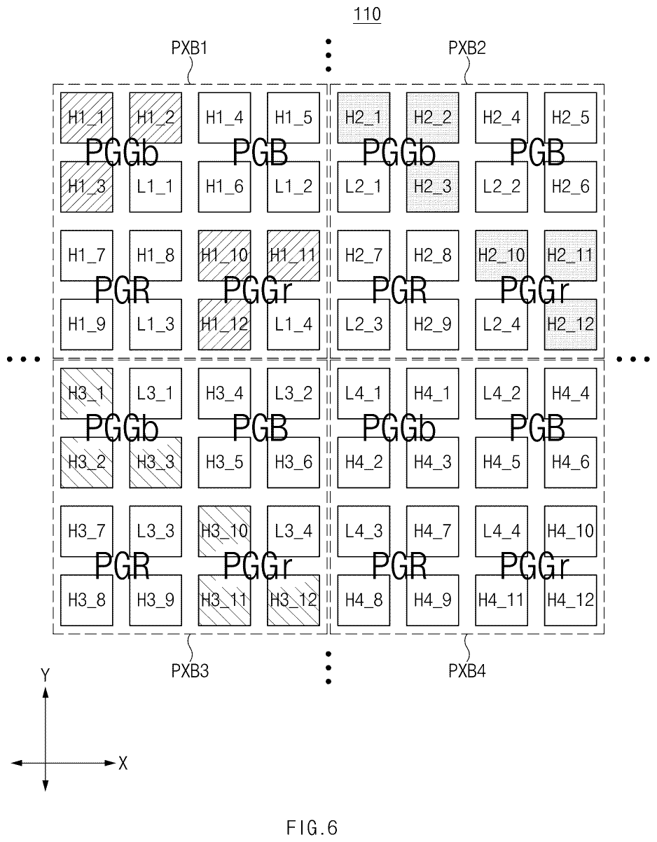

FIG. 6 is a diagram illustrating an example of the arrangement structure of pixels according to another embodiment of the disclosed technology.

Referring to FIG. 6, the pixel array 110 may include a plurality of pixel blocks (PXB1˜PXB4) arranged adjacent to each other in a first direction (e.g., an X-axis direction) and a second direction (e.g., a Y-axis direction). Each of the pixel blocks (PXB1˜PXB4) may include pixel groups (PGR, PGGr, PGGb, PGB) having the same structure as in FIG. 3.

The pixel groups (PGR, PGGr, PGGb, PGB) may include high-sensitivity pixels (H1_1˜H4_12) and low-sensitivity pixels (L1_1˜L4_4) for HDR imaging. In the example, each of the pixel blocks (PXB1˜PXB4) may include 12 high-sensitivity pixels and 4 low-sensitivity pixels, and each of the pixel groups (PGR, PGGr, PGGb, PGB) of the pixel blocks (PXB1˜PXB4) of FIG. 6 may include three high-sensitivity pixels and a single low-sensitivity pixel.

The arrangement patterns of high-sensitivity pixels between pixel blocks adjacent to each other in the first direction may be symmetrical to each other in the first direction, and the arrangement patterns of high-sensitivity pixels between pixel blocks adjacent to each other in the second direction may be symmetrical to each other in the second direction. For example, the high-sensitivity pixels in the pixel groups (PGR, PGGr, PGGb, PGB) of the pixel block (PXB1) may have a “┌”-shaped arrangement pattern. The high-sensitivity pixels in the pixel groups (PGR, PGGr, PGGb, PGB) of the pixel block (PXB2) adjacent to the pixel block (PXB1) in the first direction may have a “□”-shaped arrangement pattern. The high-sensitivity pixels in the pixel groups (PGR, PGGr, PGGb, PGB) of the pixel block (PXB3) adjacent to the pixel block (PXB1) in the second direction may have a “L”-shaped arrangement pattern. The high-sensitivity pixels in the pixel groups (PGR, PGGr, PGGb, PGB) of the pixel block (PXB4) adjacent to the pixel block (PXB3) in the first direction may have a “┘”-shaped arrangement pattern.

The image sensor 100 according to the present embodiment may include unit pixels having different photosensitivities for HDR implementation. At this time, the unit pixels having the same photosensitivity may be arranged symmetrical to each other in adjacent pixel blocks so as to implement autofocus. At this time, the arrangement patterns being symmetrical to each other in the first direction may mean that the centers of the corresponding arrangement patterns are located on the same line in the first direction, and the arrangement patterns being symmetrical to each other in the second direction may mean that the centers of the corresponding arrangement patterns are located on the same line in the second direction.

The pixel blocks (PXB1˜PXB4) arranged as in FIG. 6 may be formed at various positions within the pixel array 110.

In some implementations, the high-sensitivity pixels and the low-sensitivity pixels may be interchanged in the arrangement structure of FIG. 6. For example, the low-sensitivity pixels may be formed at the positions of the high-sensitivity pixels shown in FIG. 6, and the high-sensitivity pixels may be formed at the positions of the low-sensitivity pixels shown in FIG. 6.

In some implementations, the arrangement pattern of the high-sensitivity pixels in the pixel blocks (PXB1˜PXB4) may be changed to a different shape as long as the arrangement patterns of the high-sensitivity pixels of the pixel blocks (PXB1˜PXB4) are symmetrical to each other in the first direction or the second direction. For example, the arrangement pattern of the high-sensitivity pixels may be formed in a “┘”-shape within the pixel block (PXB1), the arrangement pattern of the high-sensitivity pixels may be formed in a “L”-shape within the pixel block (PXB2), the arrangement pattern of the high-sensitivity pixels may be formed in a “□”-shape within the pixel block (PXB3), and the arrangement pattern of the high-sensitivity pixels may be formed in a “┌”-shape within the pixel block (PXB4).

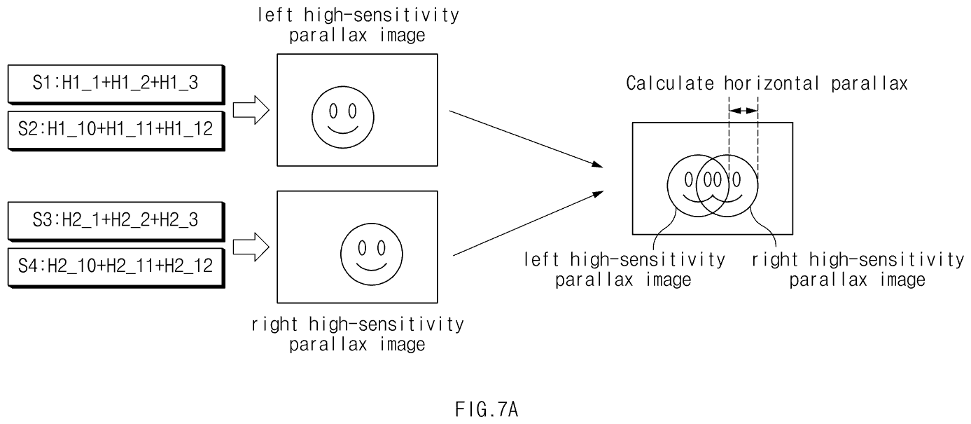

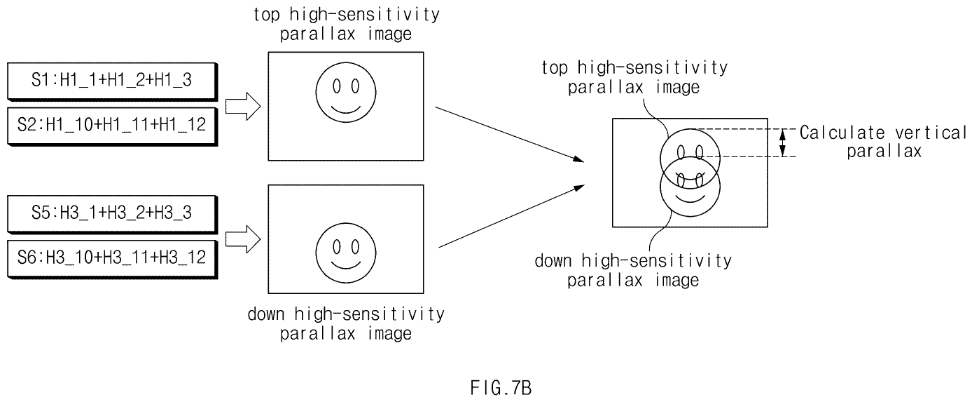

FIG. 7A is a diagram illustrating an example of a method for generating horizontal parallax images using pixel blocks of FIG. 6 and calculating a horizontal parallax using the generated horizontal parallax images according to an embodiment of the disclosed technology. FIG. 7B is a diagram illustrating an example of a method for generating vertical parallax images using pixel blocks of FIG. 6 and calculating a vertical parallax using the generated vertical parallax images according to an embodiment of the disclosed technology.

Referring to FIGS. 6 and 7A, the image sensor 100 may generate a left high-sensitivity parallax image using pixel signals of the high-sensitivity pixels (H1_1˜H1_3, H1_10˜H1_12) of the pixel groups (PGGb, PGGr) having the green color within the pixel block (PXB1). For example, the image sensor 100 may generate a left high-sensitivity parallax image by using a value (S1) obtained by summing signal values of high-sensitivity pixels (H1_1˜H1_3) of the pixel group (PGGb) and another value (S2) obtained by summing signal values of high-sensitivity pixels (H1_10˜H1_12) of the pixel group (PGGr) within the pixel block (PXB1). Although the present embodiment has disclosed that the left high-sensitivity parallax image is generated by using two values (S1, S2) as an example, other implementations are also possible. In some implementations, it should be noted that the left high-sensitivity parallax image may be generated by further using other pixel blocks in which high-sensitivity pixels have the “┌”-shaped arrangement pattern in the same manner as in the pixel block (PXB1).

In some implementations, the image sensor 100 may generate a right high-sensitivity parallax image by using pixel signals of the high-sensitivity pixels (H2_1˜H2_3, H2_10˜H2_12) of the pixel groups (PGGr, PGGb) having the green color within the pixel block (PXB2). For example, the image sensor 100 may generate a right high-sensitivity parallax image by using a value (S3) obtained by summing signal values of high-sensitivity pixels (H2_1˜H2_3) of the pixel group (PGGb) and another value (S4) obtained by summing signal values of high-sensitivity pixels (H2_10˜H2_12) of the pixel group (PGGr) within the pixel block (PXB2). Although the present embodiment has disclosed that the right high-sensitivity parallax image is generated by using two values (S3, S4) as an example, other implementations are also possible. For example, it should be noted that the left high-sensitivity parallax image may be generated by further using other pixel blocks in which high-sensitivity pixels have the “□”-shaped arrangement pattern in the same manner as in the pixel block (PXB2).

As described above, the image sensor 100 may generate the left parallax image and the right parallax image by using some unit pixels from among pixel blocks adjacent to each other in the first direction, which are located symmetrical to each other and have the same photosensitivity.

The parallax calculator 300 may calculate a first directional parallax (i.e., a horizontal parallax) by comparing the left high-sensitivity parallax image formed by the image sensor 100 with the right high-sensitivity parallax image formed by the image sensor 100.

Referring to FIGS. 6 and 7B, the image sensor 100 may generate a top high-sensitivity parallax image using pixel signals of the high-sensitivity pixels (H1_1˜H1_3, H1_10˜H1_12) of the pixel groups (PGGb, PGGr) having the green color within the pixel block (PXB1). For example, the image sensor 100 may generate a top high-sensitivity parallax image by using a value (S1) obtained by summing signal values of high-sensitivity pixels (H1_1˜H1_3) of the pixel group (PGGb) and another value (S2) obtained by summing signal values of high-sensitivity pixels (H1_10˜H1_12) of the pixel group (PGGr) within the pixel block (PXB1). According to the present embodiment, one or more parallax images generated by using the high-sensitivity pixels (H1_1˜H1_3, H1_10˜H1_12) of the pixel block (PXB1) may be used as a left high-sensitivity parallax image and a top high-sensitivity parallax image.

In addition, the image sensor 100 may generate a down high-sensitivity parallax image by using pixel signals of the high-sensitivity pixels (H3_1˜H3_3, H3_10˜H3_12) of the pixel groups (PGGr, PGGb) having the green color within the pixel block (PXB3). For example, the image sensor 100 may generate a down high-sensitivity parallax image by using a value (S5) obtained by summing signal values of high-sensitivity pixels (H3_1˜H3_3) of the pixel group (PGGb) and another value (S6) obtained by summing signal values of high-sensitivity pixels (H3_10˜H3_12) of the pixel group (PGGr) within the pixel block (PXB3). Although the present embodiment has disclosed that the down high-sensitivity parallax image is generated by using two values (S5, S6) as an example, other implementations are also possible. For example, it should be noted that the down high-sensitivity parallax image may be generated by further using other pixel blocks in which high-sensitivity pixels have the “L”-shaped arrangement pattern in the same manner as in the pixel block (PXB3).

As described above, the image sensor 100 may generate the top parallax image and the down parallax image by using some unit pixels from among pixel blocks adjacent to each other in the second direction, which are located symmetrical to each other and have the same photosensitivity.

The parallax calculator 300 may calculate a second directional parallax (i.e., a vertical parallax) by comparing the top high-sensitivity parallax image formed by the image sensor 100 with the down high-sensitivity parallax image formed by the image sensor 100.

In the arrangement structure of FIG. 6, when the positions of the high-sensitivity pixels and the positions of the low-sensitivity pixels are interchanged, the image sensor 100 may generate the left low-sensitivity parallax image, the right low-sensitivity parallax image, the top low-sensitivity parallax image, and the down low-sensitivity parallax image by using the low-sensitivity pixels in the same manner as described above. In addition, the parallax calculator 300 may calculate a first directional parallax (e.g., a horizontal parallax) by comparing the left low-sensitivity parallax image with the right low-sensitivity parallax image, and may calculate a second directional parallax (e.g., a vertical direction parallax) by comparing the top low-sensitivity parallax image with the down low-sensitivity parallax image.

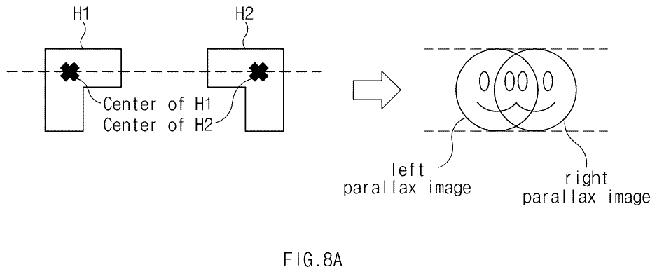

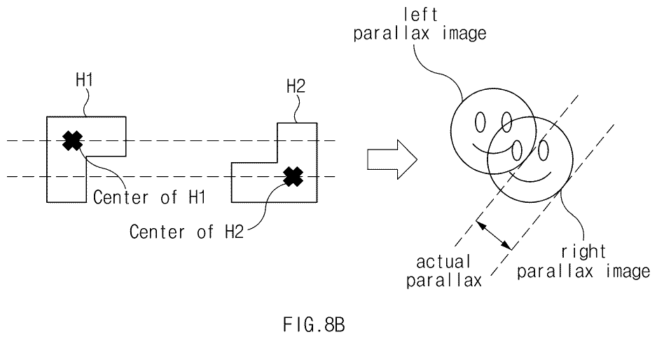

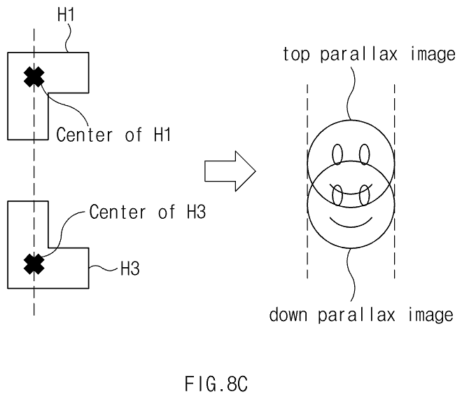

FIG. 8A is a diagram illustrating an example case in which the centers of the corresponding arrangement patterns are located on the same line in a first direction so that upper and lower positions of a left parallax image and a right parallax image are aligned. FIG. 8B is a diagram illustrating an example case in which the centers of the corresponding arrangement patterns are not located on the same line so that upper and lower positions of a left parallax image and a right parallax image are not aligned. FIG. 8C is a diagram illustrating an example case in which the centers of the corresponding arrangement patterns are located on the same line in a second direction so that left and right positions of a top parallax image and a down parallax image are aligned.

Since the left parallax image and the right parallax image for autofocus are used for calculation of a parallax in the first direction (e.g., a horizontal direction), it is desirable that the left parallax image and the right parallax image have no parallax in the second direction (e.g., a vertical direction). Similarly, since the top parallax image and the down parallax image are used to calculate a parallax in the second direction, it is desirable that the top parallax image and the down parallax image have no parallax in the first direction. To this end, the corresponding arrangement patterns need to be symmetrical to each other, that is, the centers of the arrangement patterns need to be located on the same line in the first direction or the second direction.

Referring to FIG. 8A, the arrangement patterns (H1, H2) may represent arrangement patterns of the unit pixels that are matched to each other to generate a left parallax image and a right parallax image. For example, the arrangement pattern (H1) may represent the arrangement pattern of high-sensitivity pixels (H1_1˜H1_3) of the pixel block (PXB1) shown in FIG. 6, and the arrangement pattern (H2) may represent the arrangement pattern of high-sensitivity pixels (H2_1˜H2_3) of the pixel block (PXB2) shown in FIG. 6.

As shown in FIG. 8A, when the center of the arrangement pattern (H1) for generating the left parallax image and the center of the arrangement pattern (H2) for generating the right parallax image are located on the same line in the first direction, the left parallax image and the right parallax image may be vertically aligned with each other without generating a parallax in the second direction. Therefore, the parallax calculator 300 may calculate the parallax more accurately by considering only the first directional parallax.

However, as shown in FIG. 8B, when the centers of the corresponding arrangement patterns (H1, H2) are not located on the same line, for example, when the high-sensitivity pixels (H2_1˜H2_3) of the pixel block (PXB2) shown in FIG. 6 are arranged in a “┘”-shape, the left parallax image and the right parallax image may have a first directional parallax and a second directional parallax. In this case, the parallax calculator 300 must calculate the first directional parallax by considering all parallaxes generated in the first and second directions, so that it may be impossible to accurately calculate such parallaxes. As a result, autofocusing may not be performed properly.

Referring to FIG. 8C, the arrangement patterns (H1, H3) may represent arrangement patterns of the unit pixels that are matched to each other to generate a top parallax image and a down parallax image. For example, the arrangement pattern (H1) may represent the arrangement pattern of high-sensitivity pixels (H1_1˜H1_3) of the pixel block (PXB1) shown in FIG. 6, and the arrangement pattern (H3) may represent the arrangement pattern of high-sensitivity pixels (H3_1˜H3_3) of the pixel block (PXB3) shown in FIG. 6.

As shown in FIG. 8C, when the center of the arrangement pattern (H1) for generating the top parallax image and the center of the arrangement pattern (H3) for generating the down parallax image are located on the same line in the second direction, the top parallax image and the down parallax image may be horizontally aligned without generating a parallax in the first direction. Therefore, the parallax calculator 300 may calculate the parallax more accurately by considering only the second directional parallax.

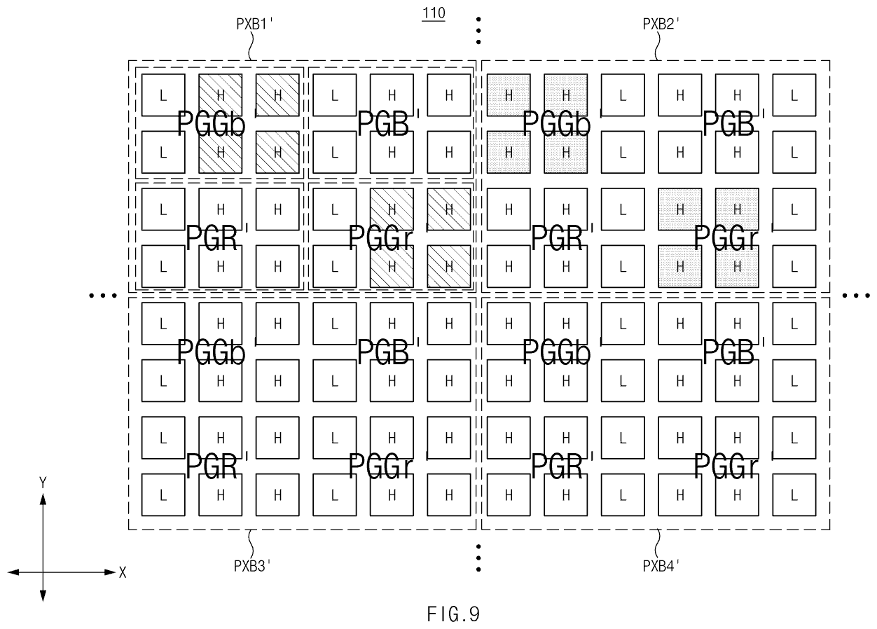

FIG. 9 is a diagram illustrating an example of the arrangement structure of pixels according to another embodiment of the disclosed technology.

Referring to FIG. 9, the pixel array 110 may include a plurality of pixel blocks (PXB1′˜PXB4′) arranged adjacent to each other in the first direction and the second direction. Each of the pixel blocks (PXB1′˜PXB4′) may include pixel groups (PGR′, PGGr′, PGGb′, PGB′) arranged in a Bayer pattern.

Each pixel group (PGR′, PGGr′, PGGb′, PGB′) may include a plurality of unit pixels sharing one microlens and arranged in a (2×3) matrix structure. Each pixel group (PGR′, PGGr′, PGGb′, PGB′) may include high-sensitivity pixels (H) and low-sensitivity pixels (L) for HDR imaging. For example, each pixel group (PGR′, PGGr′, PGGb′, PGB′) may include high-sensitivity pixels (H) arranged in a (2×2) matrix structure including two rows and two columns and low-sensitivity pixels (L) arranged in a (2×1) matrix structure including two rows and one column. At this time, in pixel blocks adjacent to each other in the first direction, the high-sensitivity pixels and the low-sensitivity pixels may be located opposite to each other in the first direction.

The pixel blocks (PXB1˜PXB4) arranged as in FIG. 9 may be formed at various positions within the pixel array 110. In some implementations, the high-sensitivity pixels and the low-sensitivity pixels may be exchanged in the arrangement structure of FIG. 9. For example, the low-sensitivity pixels may be formed at the positions of the high-sensitivity pixels shown in FIG. 9, and the high-sensitivity pixels may be formed at the positions of the low-sensitivity pixels shown in FIG. 9.

The image sensor 100 may generate first-directional parallax images using the high-sensitivity pixels or the low-sensitivity pixels of the pixel blocks (e.g., PXB1′ and PXB2′) adjacent to each other in the first direction. For example, the image sensor 100 may generate a right high-sensitivity parallax image using high-sensitivity pixels (H) of pixel groups (PGGr′, PGGb′) having the green color within the pixel block (PXB1′), and may generate a left high-sensitivity parallax image using high-sensitivity pixels (H) of pixel groups (PGGr′, PGGb′) having the green color within the pixel block (PXB2′).

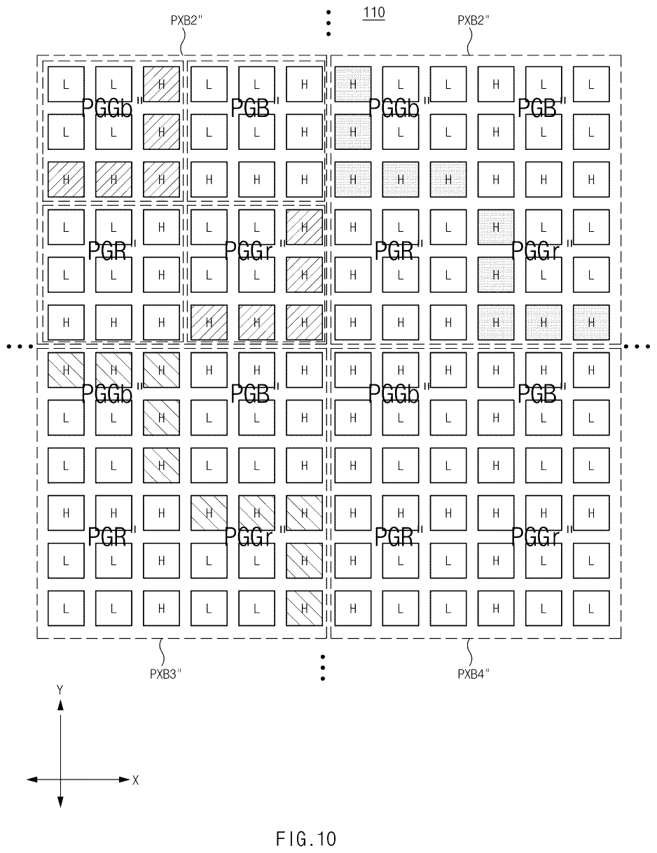

FIG. 10 is a diagram illustrating an example of the arrangement structure of pixels according to another embodiment of the disclosed technology.

Referring to FIG. 10, the pixel array 110 may include a plurality of pixel blocks (PXB1″˜PXB4″) arranged adjacent to each other in the first direction and the second direction. Each of the pixel blocks (PXB1″˜PXB4″) may include pixel groups (PGR″, PGGr″, PGGb″, PGB″) arranged in a Bayer pattern.

Each pixel group (PGR″, PGGr″, PGGb″, PGB″) may include a plurality of unit pixels sharing one microlens and arranged in a (3×3) matrix structure including three rows and three columns. Each pixel group (PGR″, PGGr″, PGGb″, PGB″) may include high-sensitivity pixels (H) and low-sensitivity pixels (L) for HDR imaging. For example, each pixel group (“PGR”, “PGGr”, “PGGb”, “PGB”) may include five high-sensitivity pixels (H) and four low-sensitivity pixels (L).

In pixel blocks adjacent to each other in the first direction or the second direction, the arrangement pattern of the high-sensitivity pixels may be symmetrical to each other in the first direction or the second direction. For example, the high-sensitivity pixels (H) in the pixel groups (PGR″, PGGr″, PGGb″, PGB″) of the pixel block (PXB1″) may have the arrangement pattern formed in the shape of “┘”. The high-sensitivity pixels (H) in the pixel groups (PGR″, PGGr″, PGGb″, PGB″) of the pixel block (PXB2″) adjacent to the pixel block (PXB1″) in the first direction may have the arrangement pattern formed in the shape of “L”. The high-sensitivity pixels (H) in the pixel groups (PGR″, PGGr″, PGGb″, PGB″) of the pixel block (PXB3″) adjacent to the pixel block (PXB1″) in the second direction may have the arrangement pattern formed in the shape of “□”. High-sensitivity pixels (H) in pixel groups (PGR″, PGGr″, PGGb″, PGB″) of pixel blocks (PXB4″) adjacent to the pixel block (PXB3″) in the first direction may have the arrangement pattern formed in the shape of “┌”.

Low-sensitivity pixels (L) in each of the pixel groups (PGR″, PGGr″, PGGb″, PGB″) of the pixel blocks (PXB1″˜PXB4″) may be arranged in a (2×2) matrix structure.

The image sensor 100 according to the present embodiment may include unit pixels having different photosensitivities for HDR implementation. At this time, the unit pixels having the same photosensitivity may be located symmetrical to each other in adjacent pixel blocks for autofocus.

The pixel blocks (PXB1″˜PXB4″) arranged as in FIG. 10 may be formed at various positions within the pixel array 110.

In some implementations, the high-sensitivity pixels (H) and the low-sensitivity pixels (L) may be interchanged in the arrangement structure of FIG. 10. For example, the low-sensitivity pixels (L) may be formed at the positions of the high-sensitivity pixels (H) shown in FIG. 10, and the high-sensitivity pixels (H) may be formed at the positions of the low-sensitivity pixels (L) shown in FIG. 10.

In some implementations, the arrangement pattern of the high-sensitivity pixels (H) in the pixel blocks (PXB1″˜PXB4″) may be changed to a different shape as long as the arrangement patterns of the high-sensitivity pixels (H) of the pixel blocks (PXB1″˜PXB4″) are symmetrical to each other in the first direction and the second direction. For example, the arrangement pattern of the high-sensitivity pixels (H) may be formed in a “┌”-shape within the pixel block (PXB1″), the arrangement pattern of the high-sensitivity pixels (H) may be formed in a “□”-shape within the pixel block (PXB2″), the arrangement pattern of the high-sensitivity pixels (H) may be formed in a “L”-shape within the pixel block (PXB3″), and the arrangement pattern of the high-sensitivity pixels (H) may be formed in a “┘”-shape within the pixel block (PXB4″).

Using the arrangement structure of FIG. 10, a method for generating parallax images having the same photosensitivity in different pixel blocks and calculating a parallax using the parallax images may be the same as the method using the arrangement structure of FIG. 6 described above.

As is apparent from the above description, the image sensor based on some implementations of the disclosed technology may generate high-sensitivity parallax images or low-sensitivity parallax images having the same parallax direction.

In addition, the image sensing system based on some implementations of the disclosed technology may detect a parallax for autofocus using the high-sensitivity images or the low-sensitivity images, and may thus detect a parallax even when the high-sensitivity images are saturated or a signal-to-noise ratio (SNR) of the low-sensitivity images is too low.

The embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. An image sensor comprising:
a first pixel block including first pixel groups arranged in a Bayer pattern; and
a second pixel block disposed adjacent to the first pixel block in a first direction and configured to include second pixel groups arranged in the Bayer pattern,
wherein
each of the first pixel groups and the second pixel groups includes first pixels and second pixels that are disposed in columns or rows and have different photosensitivities; and
the first pixels included in the first pixel groups and the first pixels included in the second pixel groups are located at opposite positions to be disposed at different columns or different rows of corresponding pixel groups.

2. The image sensor according to claim 1, wherein:
Each of the first pixel groups and the second pixel groups includes one microlens to couple incident light to different pixels.

3. The image sensor according to claim 1, wherein:
the first pixels included in the first pixel groups and the first pixels included in the second pixel groups are located opposite to each other in the first direction.

4. The image sensor according to claim 3, wherein:
each of the first pixel groups includes first pixels arranged in a (2×1) matrix structure,
each of the second pixel groups includes first pixels arranged in a (2×1) matrix structure, and
the first pixels of the first pixel group arranged in the (2×1) matrix structure and the first pixels of the second pixel group arranged in the (2×1) matrix structure are at different columns of the corresponding pixel groups.

5. The image sensor according to claim 1, wherein:
the first pixels included in the first pixel groups and the first pixels included in the second pixel group are located opposite to each other in a second direction perpendicular to the first direction.

6. The image sensor according to claim 5, wherein:
each of the first pixel groups includes first pixels arranged in a (1×2) matrix structure; and
each of the second pixel groups includes first pixels arranged in a (1×2) matrix structure, and
the first pixels of the first pixel group arranged in the (1×2) matrix structure and the first pixels of the second pixel group arranged in the (1×2) matrix structure are at different rows of the corresponding pixel groups.

7. The image sensor according to claim 1, further comprising:
a third pixel block disposed adjacent to the first pixel block in a second direction perpendicular to the first direction and configured to include a plurality of third pixel groups arranged in the Bayer pattern; and
a fourth pixel block disposed adjacent to the third pixel block in the first direction and configured to include a plurality of fourth pixel groups arranged in the Bayer pattern,
wherein
each of the plurality of third pixel groups and the plurality of fourth pixel groups includes additional first pixels and additional second pixels; and
the additional first pixels included in the plurality of third pixel groups and the additional first pixels included in the plurality of fourth pixel groups are located at opposite positions to be disposed at different columns or different rows of corresponding pixel groups.

8. The image sensor according to claim 7, wherein:
the first pixels included in the first pixel groups and the first pixels included in the second pixel groups are located opposite to each other in the first direction;
the additional first pixels included in the third pixel groups and the additional first pixels included in the fourth pixel groups are located opposite to each other in the second direction.

9. An image sensor comprising:
a first pixel block including first pixel groups arranged in a Bayer pattern; and
a second pixel block disposed adjacent to the first pixel block in a first direction and configured to include second pixel groups arranged in the Bayer pattern,
wherein
each of the first pixel groups and the second pixel groups includes a plurality of first pixels and at least one second pixel that have different photosensitivities from the plurality of first pixels; and
a first arrangement pattern of the plurality of first pixels included in the first pixel groups and a second arrangement pattern of the plurality of first pixels included in the second pixel groups are located symmetrical to each other in the first direction.

10. The image sensor according to claim 9, wherein:
in each of the first pixel groups and the second pixel groups, the plurality of first pixels and the at least one second pixel are configured to share one microlens.

11. The image sensor according to claim 9, wherein:
the first arrangement pattern is formed to have a “┌”-shape; and
the second arrangement pattern is formed to have a “□”-shape.

12. The image sensor according to claim 9, wherein:
the first arrangement pattern is formed to have a “┘”-shape; and
the second arrangement pattern is formed to have an “L”-shape.

13. The image sensor according to claim 9, wherein:
a center of the first arrangement pattern and a center of the second arrangement pattern are located on a same line in the first direction.

14. The image sensor according to claim 9, further comprising:
a third pixel block disposed adjacent to the first pixel block in a second direction perpendicular to the first direction and configured to include a plurality of third pixel groups arranged in the Bayer pattern,
wherein
each of the plurality of third pixel groups includes the plurality of first pixels and the at least one second pixel, and the plurality of first pixels included in the third pixel groups is arranged in a third arrangement pattern,
wherein
the first arrangement pattern and the third arrangement pattern are arranged symmetrical to each other in the second direction.

15. The image sensor according to claim 14, wherein:
the third arrangement pattern is formed to have a “L”-shape or a “□”-shape.

16. The image sensor according to claim 14, wherein:
a center of the first arrangement pattern and a center of the third arrangement pattern are located on a same line in the second direction.

17. An image sensing system comprising:
an image sensor that is configured to convert an optical signal for a subject into an electrical signal, include a plurality of unit pixels including first pixels having a first photosensitivity and second pixels having a second photosensitivity different from the first photosensitivity, and generate first parallax images for a first direction and second parallax images for a second direction perpendicular to the first direction by using some first pixels or some second pixels from among the plurality of unit pixels; and
a parallax calculator coupled to receive information on the first and second parallax images captured by the image sensor and structured to generate a first directional parallax by comparing the first parallax images with each other and a second directional parallax by comparing the second parallax images with each other.

18. The image sensing system according to claim 17, wherein the image sensor includes:
a first pixel block including first pixel groups arranged in a Bayer pattern; and
a second pixel block disposed adjacent to the first pixel block in a first direction and configured to include second pixel groups arranged in the Bayer pattern,
wherein
each of the first pixel groups and the second pixel groups includes the first pixels and the second pixels; and
the first pixels included in the first pixel groups and the first pixels included in the second pixel groups are located at opposite positions to be disposed at different columns or different rows of corresponding pixel groups.

19. The image sensing system according to claim 17, wherein the image sensor includes:
a first pixel block including first pixel groups arranged in a Bayer pattern; and
a second pixel block disposed adjacent to the first pixel block in a first direction and configured to include second pixel groups arranged in the Bayer pattern,
wherein
each of the first pixel groups and the second pixel groups includes the first pixels and at least one second pixel of the second pixels; and
a first arrangement pattern of the first pixels included in the first pixel groups and a second arrangement pattern of the first pixels included in the second pixel groups are located symmetrical to each other in the first direction.

20. The image sensing system according to claim 19, further comprising:
a third pixel block disposed adjacent to the first pixel block in a second direction perpendicular to the first direction and configured to include a plurality of third pixel groups arranged in the Bayer pattern,
wherein
each of the plurality of third pixel groups includes the first pixels and the at least one second pixel of the second pixels, and the first pixels included in the third pixel groups is arranged in a third arrangement pattern,
wherein
the first arrangement pattern and the third arrangement pattern are arranged symmetrical to each other in the second direction.
